(19) United States
(12) Patent Application Publication
(10) Pub. No.: US 2019/0234798 A1
(43) Pub. Date: Aug. 1, 2019

(54) TEST DEVICE AND METHOD OF MANUFACTURING LIGHT EMITTING DEVICE

(71) Applicant: Nikkiso Co., Ltd., Tokyo (JP)

(72) Inventors: Shoichi NIIZEKI, Hakusan-shi (JP); Hiroyasu ICHINOKURA, Hakusan-shi (JP)

(21) Appl. No.: 16/378,935

(22) Filed: Apr. 9, 2019

Related U.S. Application Data
(63) Continuation of application No. PCT/JP2017/033218, filed on Sep. 14, 2017.

(30) Foreign Application Priority Data
Oct. 11, 2016 (JP) 2016-200383

(51) Int. Cl. G01J 3/02; G01R 31/26; H01L 33/00

(52) U.S. Cl. CPC G01J 3/0286; G01R 31/2635; G01J 3/0218; H01L 33/0095; G01R 31/2642

(57) ABSTRACT

A test device includes: a support that supports a light emitting device subject to a test; a light waveguide that guides light output from the light emitting device supported by the support; a light diffuser plate that diffuses light output from the light waveguide; and a light receiving device that receives light diffused by the light diffuser plate. The test device may further include a constant-temperature device that houses the support and the light emitting device supported by the support and control a temperature of the light emitting device. The light receiving device may be provided outside the constant-temperature device, and the light waveguide may guide light from inside the constant-temperature device to a space outside the constant-temperature device.

### RELATED APPLICATION

Priority is claimed to Japanese Patent Application No. 2016-200383, filed on Oct. 11, 2016, the entire content of which is incorporated herein by reference.

### BACKGROUND OF THE INVENTION

### 1. Field of the Invention

The present invention relates to test devices for light emitting devices.

### 2. Description of the Related Art

Light emitting devices such as LEDs are evaluated for reliability in a current-carrying test performed for a long period of time. The test device for performing a current-carrying test like this is exemplified by a test device capable of testing a semiconductor light emitting device in an environment of a temperature lower or higher than the room temperature, without mounting a light component carrying the semiconductor light emitting device on a substrate, etc.

In the case of testing a light emitting device capable of outputting light such as deep ultraviolet light having a short wavelength and a high energy, the light receiving device provided in the test device may be degraded due to the high-energy light, which may result in a failure to properly perform a current-carrying test for a long period of time. This has a consequence of detracting from the reliability of the testing step.

### SUMMARY OF THE INVENTION

In this background, one illustrative purpose of the present invention is to provide a test device capable of performing a highly reliable continuous current-carrying test.

A test device according to an embodiment includes: a support that supports a light emitting device subject to a test; a light waveguide that guides light output from the light emitting device supported by the support; a light diffuser plate that diffuses light output from the light waveguide; and a light receiving device that receives light diffused by the light diffuser plate.

According to the embodiment, the light transmitted by the light waveguide and having an increased peak intensity near the center accordingly is diffused by the light diffuser plate, and the light with a decreased peak intensity as a result of diffusion is caused to be incident on the light receiving device. This reduces the impact from high-intensity light being concentrated on a restricted part of the light receiving surface to degrade the part earlier than the other parts, and extends the life of the light receiving device until it becomes unavailable. By allowing the light receiving device to be used for a long period of time, a current-carrying test can be performed properly for a long period of time and reliability of the test is improved.

The test device may further include a constant-temperature device that houses the support and the light emitting device supported by the support inside and controls an operating temperature of the light emitting device. The light receiving device may be provided outside the constant-temperature device, and the light waveguide may guide light from inside the constant-temperature device to an area outside the constant-temperature device.

The test device may further include a shield plate provided to shield light traveling toward an outer peripheral area of a light receiving surface of the light receiving device.

The light emitting device may output deep ultraviolet light having a wavelength of 360 nm or shorter.

The light waveguide may be formed by a rod of quartz (SiO₂) glass.

The light diffuser plate may be a quartz glass plate having a concavo-convex surface for diffusing light.

Another embodiment relates to a method of manufacturing a light emitting device. The method includes receiving light output from a light emitting device via a light waveguide and a light diffuser plate and testing an optical output of the light emitting device.

According to the embodiment, the light transmitted by the light waveguide and having an increased peak intensity near the center accordingly is diffused by the light diffuser plate, and the light with a decreased peak intensity as a result of diffusion is caused to be incident on the light receiving device. This reduces the impact from high-intensity light being concentrated on a restricted part of the light receiving surface to degrade the part earlier than the other parts, and extends the life of the light receiving device until it becomes unavailable. This prevents the reliability of the test from being reduced due to early degradation of the light receiving device and provides a highly reliable light emitting device that has been tested properly.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 schematically shows a configuration of a test device according to the embodiment; and

FIG. 2 is a graph schematically showing the intensity distribution of light output from the light guide.

### DETAILED DESCRIPTION OF THE INVENTION

The invention will now be described by reference to the preferred embodiments. This does not intend to limit the scope of the present invention, but to exemplify the invention.

A detailed description will be given of embodiments of the present invention with reference to the drawings. Like numerals are used in the description to denote like elements and a duplicate description is omitted as appropriate.

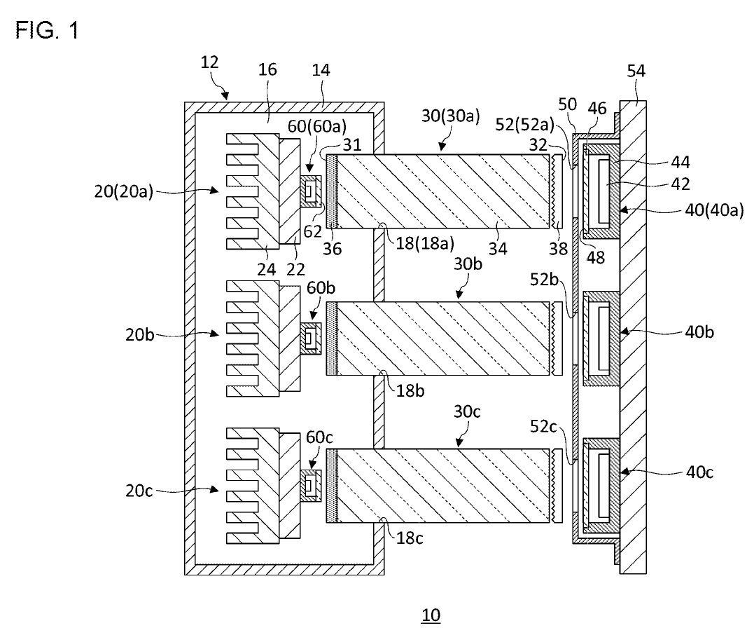

FIG. 1 schematically shows a configuration of a test device 10 according to the embodiment. The test device includes a constant-temperature device 12, a plurality of supports 20 (20a, 20b, 20c), a plurality of light guides 30 (30a, 30b, 30c), a plurality of light receiving devices 40 (40a, 40b, 40c), and a shield plate 50. The test device 10 is a device for performing a current-carrying test of a plurality of light emitting devices 60 (60a, 60b, 60c) collectively.

The light emitting device 60 tested is an ultra violet-light emitting diode (UV-LED) for outputting deep ultraviolet light. The light emitting device 60 is configured to output deep ultraviolet light having a peak wavelength or a central wavelength in a range 200 nm˜360 nm. Such a deep ultraviolet LED is exemplified by an aluminum gallium nitride (AlGaN) based LED.

The constant-temperature device 12 includes a container 14 that houses inside the plurality of supports 20 and the light emitting devices 60 respectively supported by the plurality of supports 20. The constant-temperature device 12 is a device exemplified by a constant-temperature tank that heats or cools an interior space 16 bounded by the container 14 to be maintained at a constant temperature. The constant-temperature device 12 maintains the temperature condition used in the current-carrying test of the light emitting device 60 to be maintained over a predetermined test period. The constant-temperature device 12 may be configured to perform a cycle test in which the temperature is increased and decreased at a predetermined period. The container 14 is provided with a plurality of mounting holes 18 (18a, 18b, 18c) for guiding the plurality of light guides 30 therethrough.

The support 20 supports the light emitting device 60 under test. The support 20 includes a substrate 22 for carrying the light emitting device and a heat sink 24. The substrate 22 for carrying the light emitting device includes a terminal connected to the electrode of the light emitting device 60 and supplies a drive current for driving the light emitting device 60 via the terminal. The substrate 22 for carrying the light emitting device is connected to an external electrode (not shown). The heat sink 24 is attached to the substrate 22 for carrying the light emitting device. The heat sink 24 helps the temperature of the substrate 22 for carrying the light emitting device and the light emitting device 60 to be equal to the temperature in the interior space 16 of the constant-temperature device 12.

The plurality of supports 20 are provided inside the constant-temperature device 12. In the illustrated example, three supports 20 are provided, but the number of supports 20 may be two or less or four or more. The plurality of supports 20 may be arranged in a row (one-dimensional array) or arranged in a matrix (two-dimensional array) inside the constant-temperature device 12. In one embodiment, the plurality of supports 20 may be arranged in a matrix of 5×15. In the illustrated example, the support 20 is configured to support one light emitting device 60. In a variation, one support may be configured to support a plurality of light emitting devices 60. For example, the plurality of supports 20a, 20b, and 20c may be integrated so that the one support may carry three light emitting devices 60.

The support 20 is arranged such that the output light from the light emitting device 60 carried on the support 20 is incident on the associated light guide 30. The support 20 is arranged such that a light emission surface 62 of the light emitting device 60 carried by the support 20 faces a light incidence end 31 of the light guide 30, and, preferably, such that the light emission surface 62 of the light emitting device 60 is proximate to the light incidence end 31 of the light guide 30. The support 20 is housed inside the constant-temperature device 12 when the test device 10 is used, but the support 20 may be configured so that it can be easily taken outside the constant-temperature device 12 when the test device 10 is not used. For example, the support 20 may be configured such that it can be housed in a rack provided inside the constant-temperature device 12.

The light guide 30 is provided between the light emitting device 60 and the light receiving device 40 associated with the light guide 30 and is configured to guide the output light from the light emitting device 60 to the light receiving device 40. The light guide 30 is provided to extract the output light of the light emitting device 60 from inside the constant-temperature device 12 to an area outside. The light incidence end 31 of the light guide 30 is provided inside the constant-temperature device 12 and is positioned near the light emitting device 60 carried on the support 20. Meanwhile, the light emission end 32 of the light guide 30 is provided outside the constant-temperature device 12 and is positioned near a light receiving surface 48 of the light receiving device 40.

The light guide 30 includes a light waveguide 34, a light amount filter 36, and a light diffuser plate 38. The light waveguide 34 is a member extending from the associated light emitting device 60 to the light receiving device 40 in the longitudinal direction. The light waveguide 34 is desirably made of a material not easily degraded by the ultraviolet light output by the light emitting device 60. For example, the light waveguide 34 is made of quartz (SiO₂) glass. The light waveguide 34 is formed by, for example, a columnar quartz glass rod. The light waveguide 34 has a cross-sectional area larger than that of the light emission surface 62 of the light emitting device 60. For example, the dimension (diameter) of the cross-sectional surface is 5 mm or larger. In one embodiment, the diameter of the light waveguide 34 is about 6 mm.

The light waveguide 34 may include a core and a clad such as those of the optical fiber or may be comprised only of a core. The light waveguide 34 may be a hollow tube, a quartz tube, a fluororesin (e.g., polytetrafluoroethylene) tube, or a resin tube or a metal tube having an aluminum inner surface. The shape of the cross-section perpendicular to the longitudinal direction of the light waveguide 34 is not limited to any particular shape. For example, the cross section may be shaped in a circle, ellipse, triangle, quadrangle, pentagon, and hexagon. The light waveguide 34 may be comprised of a bundle of a plurality of optical fibers.

The light amount filter 36 is a so-called neutral density (ND) filter and attenuates the intensity of light transmitted by the light guide 30 by a certain proportion. The transmittance of the light amount filter 36 is not limited to any particular value. For example, values like 1%, 5%, 10%, 20%, etc. can be used. It is preferred that the light amount filter 36 be made of a material that cannot be easily degraded by deep ultraviolet light. For example, quartz glass is used as a base material. Using a material having a high durability against deep ultraviolet light reduces the impact from degradation due to ultraviolet light that causes the filter transmittance to vary with time.

The light amount filter 36 is provided at the light incidence end 31 of the light guide 30 and is provided between the light emitting device 60 and the light waveguide 34. Providing the light amount filter 36 before the light waveguide 34 reduces the impact from high-intensity deep ultraviolet light incident on the light waveguide 34 that degrades the light waveguide 34. In one variation, the light amount filter 36 may be provided between the light waveguide 34 and the light receiving device 40. Specifically, the light amount filter 36 may be provided between the light waveguide 34 and the light diffuser plate 38 or between the light diffuser plate 38 and the light receiving device 40.

The light diffuser plate 38 is provided at the light emission end 32 of the light guide 30. The light diffuser plate 38 diffuses the light output from the light waveguide 34 and conditions the intensity distribution of the light incident on the light receiving device 40. The light diffuser plate 38 makes the intensity distribution of the output light from the light waveguide 34 uniform. In other words, the light diffuser plate 38 lowers the peak intensity value of the output light and enlarges the full width at half maximum value of the intensity distribution. It is preferred that the light diffuser plate 38 be made of a material that is not easily degraded by deep ultraviolet light. For example, quartz glass is used as a base material. The light diffuser plate 38 may be a so-called “frosted glass” and produced by forming fine concavo-convex surfaces for diffusing light on a principal surface of both surfaces a quartz glass plate. For the purpose of light diffusion, it is preferred to form the concavo-convex surfaces to have a uniform and compact sand finish.

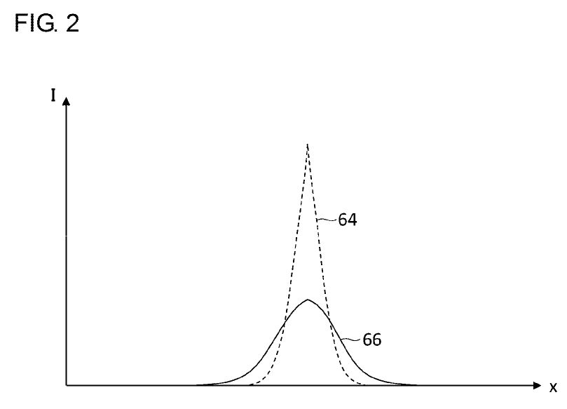

FIG. 2 is a graph schematically showing the intensity distribution of light output from the light guide 30 and shows the distribution of light intensity I in the direction along the light receiving surface 48 (x direction). A broken line 64 shows an example of intensity distribution of light output from the light waveguide 34 in the absence of the light diffuser plate 38. The output light from the light waveguide 34 exhibits an intensity distribution having a strong peak near the center, i.e., an intensity distribution as illustrated having a sharp peak and a small spread. A solid line 66 indicates an example of intensity distribution of light output from the light guide 30 in the presence of the light diffuser plate 38. By transmitting the light through the light diffuser plate 38, diffused light with an intensity distribution having a lower peak intensity and a lager spread than those indicated by the broken line 64 is output.

The light receiving device 40 is provided outside the constant-temperature device 12 and receives the light transmitted by the light guide 30. Each of the light receiving devices 40 receives the light output from the associated light emitting device 60. For example, the first light receiving device 40a receives the light output from the first light emitting device 60a and transmitted by the first light guide 30a. Similarly, the second light receiving device 40b receives the light output from the second light emitting device 60b and transmitted by the second light guide 30b, and the third light receiving device 40c receives the light output from the third light emitting device 60c and transmitted by the third light guide 30c. The plurality of light receiving devices 40 are attached to a substrate 54 for carrying the light receiving device.

The light receiving device 40 includes a light receiving element 42, a package 44, and a light receiving window 46. The light receiving element 42 is a photoelectric conversion element such as a photodiode and measures the intensity of incident light. The light receiving element 42 may be configured to measure the intensity distribution of incident light. The light receiving element 42 is housed inside the package 44. The light receiving window 46 transmits the light traveling toward the light receiving element 42. The light receiving window 46 is attached to the package 44. The light receiving window 46 and the package 44 seal the light receiving element 42 inside the package 44. For example, the light receiving window 46 is attached to the package 44 by an adhesive provided on the outer periphery of the light receiving window 46. The light receiving window 46 forms the light receiving surface 48 on which the light that should be measured by the light receiving device 40 is incident.

The shield plate 50 is provided between the light guide 30 and the light receiving device 40. The shield plate 50 has a plurality of openings 52 (52a, 52b, 52c) that transmit the light traveling toward the central area of the light receiving surfaces 48 of the plurality of light receiving devices 40 (40a, 40b, 40c). The opening 52 has a shape corresponding to the shape of the light receiving surface 48 of the light receiving device 40. For example, the opening 52 is shaped in a circle or a rectangle. The shield plate 50 transmits the light traveling toward the central area of the light receiving surface 48 of the light receiving device 40 but shields the light traveling toward the outer periphery of the light receiving surface 48. This prevents the adhesive agent bonding the package 44 and the light receiving window 46 from being irradiated with deep ultraviolet light and degraded so as to detract from the sealing performance of the package 44.

A description will now be given of a method of using the test device 10. First, the light emitting device 60 is carried on each of the plurality of supports 20. The interior of the constant-temperature device 12 is set to a predetermined temperature and the light emitting device 60 is lighted. The deep ultraviolet light emitted by the light emitting device 60 has its intensity attenuated by the light amount filter 36 and is transmitted by the light waveguide 34. The light diffuser plate 38 uniformizes the intensity distribution. The light receiving device 40 receives the light transmitted by the light guide 30. The light emitting device 60 is caused to carry a current continuously for a period of time necessary for the test (e.g., 100 hours, 1000 hours, 5000 hours, 10000 hours, 50000 hours). The light receiving device 40 measures the intensity or intensity distribution of the incident light over the period of time for which the continuous current-carrying test is performed.

According to the embodiment, a current-carrying test of the light emitting device 60 outputting deep ultraviolet light is performed, while suitably preventing degradation of the light guide 30 and the light receiving device 40 due to the deep ultraviolet light. Ultraviolet light having a wavelength of 360 nm or shorter has a high light energy (3.4 eV or higher). Therefore, the material used in the light guide 30 and the light receiving device 40 in the relate-art test device configuration are damaged, damaging the light guide 30 and the light receiving device 40. If an ordinary optical glass or resin material is used as a material of the light guide 30, for example, the light guide 30 is degraded by the impact from deep ultraviolet light, resulting in optical materials turning yellow and/or brittle. Further, a semiconductor material like silicon (Si) used in the light receiving element 42 may be degraded when receiving a high-intensity deep ultraviolet light and could not be used continuously for a long period of time. For example, our experiment with measurement of the output light from the light emitting device 60 of a wavelength 300 nm and an optical output of 30 mW without the light amount filter 36 nor the light diffuser plate 38 revealed that, after about 1000 hours, the neighborhood of the center of the light receiving element 42 turns black and the light intensity can no longer be measured accurately. Meanwhile, it was found out that the use of a combination of the light amount filter 36 with a transmittance of 10% and the light diffuser plate 38 with #220 sand finish extends the life of the light receiving device 40 to about 50000 hours. Therefore, the test device 10 according to the embodiment makes it possible to perform a continuous current-carrying test for long period of time and enhance the reliability of the life test of the light emitting device 60.

According to the embodiment, the light receiving device 40 is provided outside the constant-temperature device 12 so that the light receiving device 40 of a specification for the operation under room temperature can be used. This eliminates the necessity of preparing a special light receiving device 40 that can be operated in a low or high temperature so that the cost for the light receiving device 40 is reduced. The test device is configured such that the shield plate 50 protects the joint between the package 44 of the light receiving device 40 and the light receiving window 46 so that there is no need to use a light receiving device 40 of a specification for high resistance to light and the cost of the light receiving device 40 is reduced accordingly.

According to the embodiment, the light output from the light waveguide 34 and having a high peak intensity is diffused by using the light diffuser plate 38 before being received by the device. It is therefore possible for the light receiving device 40 to make a highly sensitive measurement by taking full advantage of the effective area capable of receiving light. This enhances the reliability of the light emission test using the test device 10.

A description will now be given of a method of manufacturing the light emitting device 60 including a testing step that uses the test device 10. First, a semiconductor light emitting device formed by an aluminum gallium nitride (AlGaN) based semiconductor material is fabricated, and the light emitting device 60 is manufactured by sealing the light emitting device thus fabricated in an LED package. Subsequently, a lighting test of the light emitting device 60 is performed by using the test device 10. In a light emitting test, the light output from the light emitting device 60 is received by the light receiving device 40 via the light amount filter 36, the light waveguide 34, and the light diffuser plate 38 to test the optical output of the light emitting device 60. The testing step may be a burn-in test in which a current is carried for a predetermined period of time in a high-temperature environment in order to stabilize the characteristics and eliminate irregular products or defective products. The light emitting device 60 may be completed by undergoing a burn-in test. In this manufacturing method, the test is performed by using the test device 10 that is not easily affected by deep ultraviolet light so that the reliability of the testing step is enhanced, and the reliability of the light emitting device 60 shipped is enhanced.

Described above is an explanation based on an exemplary embodiment. The embodiment is intended to be illustrative only and it will be understood by those skilled in the art that various design changes are possible and various modifications are possible and that such modifications are also within the scope of the present invention.

In the above embodiment, the test device 10 is described as using one constant-temperature device 12. In one variation, the test device 10 may be provided with a plurality of constant-temperature devices 12. The plurality of constant-temperature devices 12 may be arranged in a row or arranged in a matrix (e.g., 2×2). The plurality of supports 20 may be provided in each of the plurality of constant-temperature devices 12. By using a plurality of constant-temperature devices 12, tests with different temperature conditions can be performed at the same time to increase the efficiency of tests.

In the above embodiment, the case of testing the light emitting device 60 for outputting deep ultraviolet light has been described. In one variation, the test device 10 described above may be used for a light emitting device for outputting light other than deep ultraviolet light. For example, a light emitting device for outputting ultraviolet light of 360 nm˜400 nm or a light emitting device for outputting blue light of 400 nm˜450 nm may be tested. Light emitting devices for outputting visible light such as green light, yellow light, and red light may be tested, or light emitting devices for outputting infrared light may be tested.

It should be understood that the invention is not limited to the above-described embodiment but may be modified into various forms on the basis of the spirit of the invention. Additionally, the modifications are included in the scope of the invention.

What is claimed is:

1. A test device comprising:
a support that supports a light emitting device subject to a test;
a light waveguide that guides light output from the light emitting device supported by the support;
a light diffuser plate that diffuses light output from the light waveguide; and
a light receiving device that receives light diffused by the diffuser plate.

2. The test device according to claim 1, further comprising
a constant-temperature device that houses the support and the light emitting device supported by the support inside and controls an operating temperature of the light emitting device, wherein
the light receiving device is provided outside the constant-temperature device, and the light waveguide guides light from inside the constant-temperature device to an area outside the constant-temperature device.

3. The test device according to claim 1, further comprising:
a shield plate provided to shield light traveling toward an outer peripheral area of a light receiving surface of the light receiving device.

4. The test device according to claim 1, wherein
the light emitting device outputs deep ultraviolet light having a wavelength of 360 nm or shorter.

5. The test device according to claim 1, wherein
the light waveguide is formed by a rod of quartz (SiO₂) glass.

6. The test device according to claim 1, wherein
the light diffuser plate is a quartz glass plate having a concavo-convex surface for diffusing light.

7. A method of manufacturing a light emitting device comprising:
receiving light output from a light emitting device via a light waveguide and a light diffuser plate and testing an optical output of the light emitting device.
